(19) United States
(12) Patent Application Publication
(10) Pub. No.: US 2010/0051331 A1
(43) Pub. Date: Mar. 4, 2010

(54) CIRCUIT SUBSTRATE FOR MOUNTING ELECTRONIC COMPONENT AND CIRCUIT SUBSTRATE ASSEMBLY HAVING SAME

(75) Inventors: CHUNG-JEN TSAI, Tayuan (TW); HUNG-YI CHANG, Tayuan (TW); CHIA-CHENG CHEN, Tayuan (TW); CHENG-HSIEN LIN, Tayuan (TW)

Correspondence Address: PCE INDUSTRY, INC.;ATT. Steven Reiss, 288 SOUTH MAYO AVENUE, CITY OF INDUSTRY, CA, 91789, US

(73) Assignee: FOXCONN ADVANCED TECHNOLOGY INC., Tayuan (TW)

(21) Appl. No.: 12/468,841

(22) Filed: May 19, 2009

(30) Foreign Application Priority Data
Aug. 27, 2008 (CN) 200810304249.6

(51) Int. Cl. H05K 1/03

(52) U.S. Cl. 174/256; 977/742

(57) ABSTRACT

A circuit substrate for mounting electronic components includes a metal base layer, an electrically conductive layer having electrically conductive traces, and a composite layer disposed between the metal base layer and the electrically conductive layer. The composite layer includes a polymer matrix and a number of carbon nanotubes embedded in the polymer matrix. The composite layer has a first surface in contact with the metal substrate and an opposite second surface. Each of the carbon nanotubes extends from the first surface to the second surface inclined at an angle of from 80° to 100° relative to the first surface.

### CROSS-REFERENCE TO RELATED APPLICATIONS

This application is related to a commonly-assigned co-pending application application Ser. No. 12/135,849 entitled, “FLEXIBLE PRINTED CIRCUIT BOARD BASE FILM, FLEXIBLE LAMINATES AND FLEXIBLE PRINTED CIRCUIT BOARDS INCLUDING SAME”, filed on the 9 Jun. 2008. Disclosures of the above identified application are incorporated herein by reference.

### BACKGROUND

1. Technical Field

The disclosure relates to packaging substrates, and particularly to a circuit substrate for mounting an electronic component and a circuit substrate assembly having the circuit substrate and the electronic component.

2. Description of Related Art

Printed circuit boards (PCBs) are widely used in various electronic devices such as mobile phones, printing heads, and hard disk drives, providing electrical transmission. With the development of electronic technology, PCBs required high circuit density and multilayer PCBs thus often replace single sided or double sided PCBs.

A thermal dissipation of a PCB is not a concern when the PCB is single sided or double sided, but becomes critical when the PCB carries electronic components, especially for a multilayer PCB carrying electronic components. Generally, PCBs are made from copper clad laminates, which include resin layers and copper layers. However, the resin layers provide poor coefficient of thermal conductivity, such that residual heat generated by the electronic components is problematic.

Therefore, it is desirable to provide a circuit substrate for mounting an electronic component having improved heat dissipation and a circuit substrate assembly having the circuit substrate and the electronic component.

### BRIEF DESCRIPTION OF THE DRAWINGS

Many aspects of the present embodiment can be better understood with reference to the following drawings. The components in the drawings are not necessarily drawn to scale, the emphasis instead being placed upon clearly illustrating the principles of the present embodiment. Moreover, in the drawings, like reference numerals designate corresponding parts throughout the several views.

FIG. 1 is a cross sectional view of a circuit substrate in accordance with a first embodiment.

FIG. 2 is a cross sectional view of a circuit substrate in accordance with a second embodiment.

FIG. 3 is a cross sectional view of a circuit substrate in accordance with a third embodiment.

FIG. 4 is a flowchart of a method for manufacturing the circuit substrate of FIG. 1.

FIG. 5 is a cross sectional view of a sacrificial layer.

FIG. 6 is similar to FIG. 5, but showing a catalyst layer formed on the sacrificial layer.

FIG. 7 is similar to FIG. 6, but showing a carbon nanotube array formed on the catalyst layer.

FIG. 8 is similar to FIG. 7, but showing an end of the carbon nanotube array being covered by a polymer.

FIG. 9 is similar to FIG. 8, but showing the catalyst layer and the sacrificial layer being removed.

FIG. 10 is similar to FIG. 9, but showing another end of the carbon nanotube array being covered by the polymer thereby an composite layer being obtained

FIG. 11 is similar to FIG. 10, but showing a metal base layer and an electrically conductive layer formed on two opposite surfaces of the composite layer.

FIG. 12 is a cross sectional view of a circuit substrate assembly comprising a circuit substrate such as, for example, that of FIG. 3.

### DETAILED DESCRIPTION

Embodiments will now be described in detail below and with reference to the drawings.

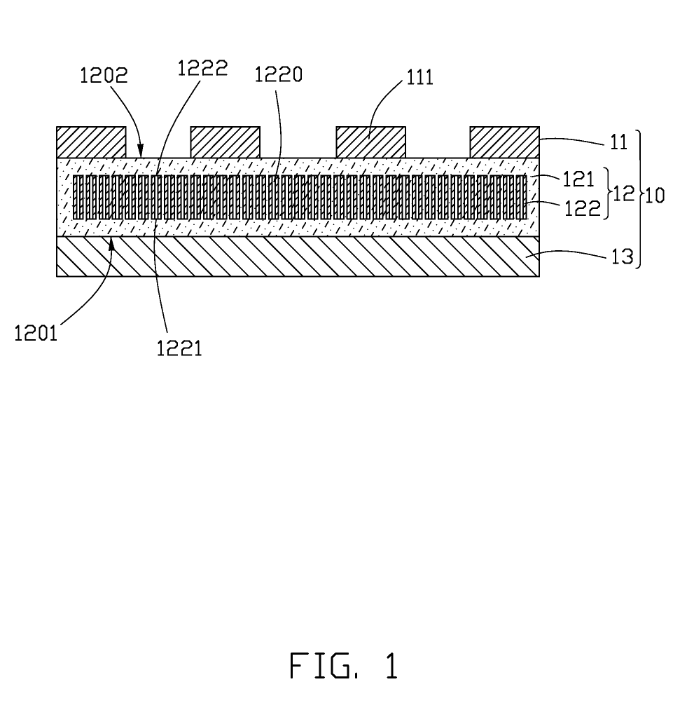

FIG. 1 illustrates a circuit substrate 10 for mounting electronic components in accordance with a first embodiment. The circuit substrate 10 includes an electrically conductive layer 11, a composite layer 12, and a metal base layer 13 in sequence. The electrically conductive layer 11 can be a copper layer, and has a plurality of electrically conductive traces 111 formed therein. The electrically conductive traces 111 are configured for transmitting electrical signals and electrically communicating with the electronic components. The composite layer 12 is positioned between the electrically conductive layer 11 and the metal base layer 13, and has a first surface 1201 in contact with the metal base layer 13 and a second surface 1202 in contact with the electrically conductive layer 11. The composite layer 12 is configured for conducting heat from the second surface 1202 to the first surface 1201, that is from the electrically conductive layer 11 to the metal base layer 13. The metal base layer 13 can be any material with high thermal conductivity, such as copper or aluminum, and is configured for dissipating heat transmitted from the first surface 1201 of the composite layer 12.

Specifically, the composite layer 12 includes a polymer matrix 121 and a carbon nanotube (CNT) array 122 embedded therein. A volume content of the CNT array 122 in the composite layer 12 can be from 40% to 80%. The polymer matrix 121 can be comprised of polyimide, polyethylene terephtalate, polytetrafluorethylene, polyaminde, polymethylmethacrylate, polycarbonate, polyamide polyethylene-terephthalate copolymer, glass fiber/resin compound, or other materials. The CNT array 122 includes a plurality of CNTs 1220 substantially parallel to each other. The CNTs 1220 can be single-wall carbon nanotubes or multi-wall carbon nanotubes. Each of the CNTs 1220 extends from the first surface 1201 to the second surface 1202 inclined at an angle of from about 80° to about 100° relative to the first surface 1201. In other words, the CNTs 1220 are substantially perpendicular to the first surface 1201 and the second surface 1202.

Each of the CNTs 1220 has a first end 1221 adjacent to the first surface 1201 and an opposite second end 1222 adjacent to the second surface 1202. A distance between the first end 1221 and the second end 1222, i.e., a length of each of the CNTs 1220, is less than a thickness of the composite layer 12. The length of each of the CNTs 1220 is preferably about 60%-90% of the thickness of the composite layer 12. Generally, the length of each of the CNTs 1220 is from about 1 micrometer (μm) to about 30 μm.

At least one end of each of the CNTs 1220 is buried under and not exposed by one surface of the composite layer 12. In the illustrated embodiment, the first end 1221 and the second end 1222 are all buried in the polymer matrix 121, and spaced a distance from the first surface 1201 and the second surface 1202. In other words, the first end 1221 and the second end 1222 are all positioned between the first surface 1201 and the second surface 1202, the first end 1221 is spaced a distance from the first surface 1201, and the second end 1222 is spaced a distance from the second surface 1202. Preferably, a distance between the first end 1221 and the first surface 1201 is equal to that between the second end 1222 and the second surface 1202.

In addition, a distance between each two neighboring CNTs 1220 in the composite layer 12 can be a constant. That is, CNTs 1220 can be uniformly distributed in the composite layer 12. It is noted that the CNTs 1220 can also be randomly distributed in the composite layer 12, for example, the CNTs 1220 can also be distributed with a distribution density varying in a given direction perpendicular to a thickness of the composite layer 12.

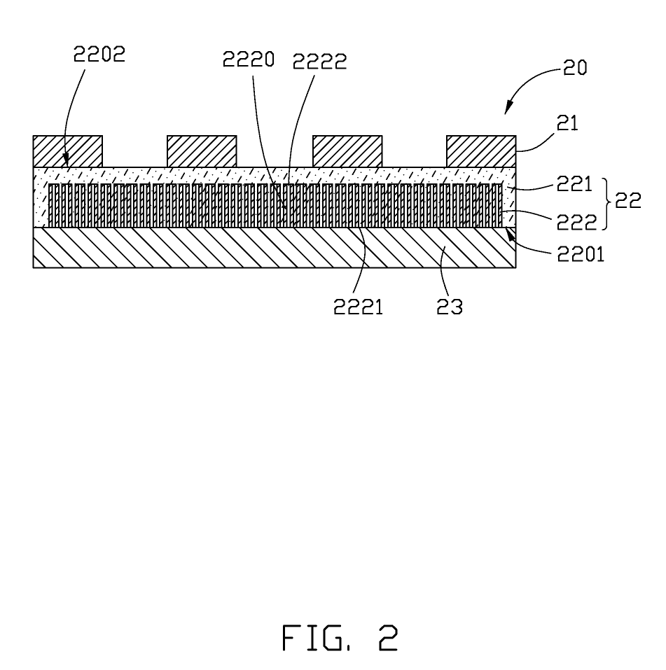

Referring to FIG. 2, a circuit substrate 20 in accordance with a second embodiment is similar to that of the first embodiment, and also includes an electrically conductive layer 21, a composite layer 22, and a metal base layer 23 in sequence. The electrically conductive layer 21 has a plurality of electrically conductive traces formed therein. The metal base layer 23 can be made of material with a high thermal conductivity, such as copper or aluminum. The composite layer 22 is positioned between the electrically conductive layer 21 and the metal base layer 23, and has a first surface 2201 in contact with the metal base layer 23 and a second surface 2202 in contact with the electrically conductive layer 21.

The composite layer 22 also includes a polymer matrix 221 and a CNT array 222 embedded in the polymer matrix 221. The CNT array 222 also includes a plurality of substantially parallel CNTs 2220. Distribution of the CNT array 222 is similar to that of the CNT array 122 of the first embodiment except that a first end 2221 of each of the CNTs 2220 is in contact with the metal base layer 23. In other words, the first end 2221 is exposed at the first surface 2201, and a second end 2222 of each of the CNTs 2220 is adjacent to and spaced a distance from the second surface 2202. Each of the CNTs 2220 also extends from the first surface 2201 to the second surface 2202 inclined at an angle from 80° to 100° relative to the first surface 2201.

In the illustrated embodiment, the length of each of the CNTs 2220 can be about 60%-90% of the thickness of the composite layer 22, and preferably about 75%-90% of the thickness of the composite layer 22.

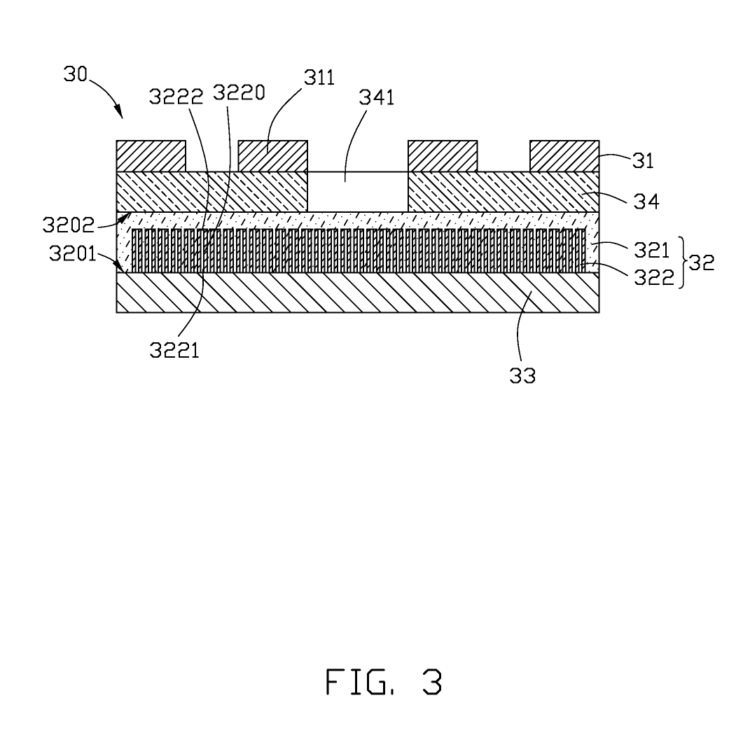

Referring to FIG. 3, a circuit substrate 30 in accordance with a third embodiment is similar to that of the second embodiment, and includes an electrically conductive layer 31, an insulating layer 34, a composite layer 32, and a metal base layer 33 in sequence. The electrically conductive layer 31 has a plurality of electrically conductive traces 311 defined therein. The insulating layer 34 is positioned between the electrically conductive layer 31 and the composite layer 32. The composite layer 32 has structures similar to the composite layer 22 of the second embodiment, and has a first surface 3201 in contact with the metal base layer 33 and a second surface 3202 in contact with the insulating layer 34. The composite layer 32 also includes a polymer matrix 321 and a CNT array 322 embedded in the polymer matrix 321. The CNT array 322 also includes a plurality of substantially parallel CNTs 3220. A first end 3221 of each of the CNTs 3220 is exposed at the first surface 3201 and in contact with the metal base layer 33, and a second end 3222 of each of the CNTs 3220 is buried under the second surface 3202. That is, a second end 3222 of each of the CNTs 3220 is adjacent to and spaced a distance from the second surface 3202.

In addition, a through hole 341 is defined in the insulation layer 34, and is configured for accommodating an electronic component which can be mounted on the circuit substrate 30 and electrically connecting to the electrically conductive traces 311 of the electrically conductive layer 31.

In the circuit substrates 10, 20, and 30, CNT arrays 122, 222, and 322 are buried under at least one surface of the composite layers 12, 22, and 32, respectively; therefore, the conductive layers 11, 21, and 31 can be electrically isolated from the metal base layers 13, 23, and 33, respectively. Due to the high thermal conductivity of CNTs 1220, 2220, and 3220 of the composite layers 12, 22, and 32, heat can be efficiently conducted from the electrically conductive layers 11, 21, and 31 to the metal base layers 13, 23, and 33, respectively.

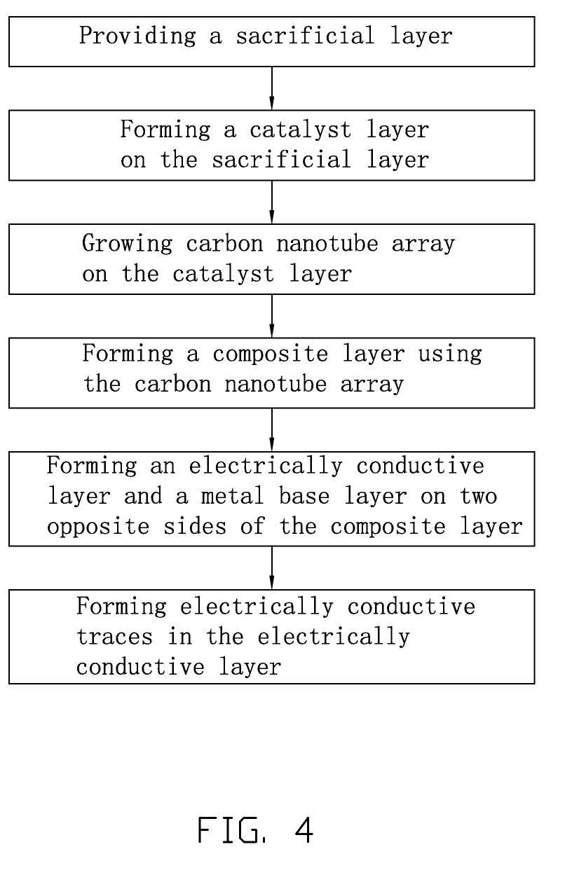

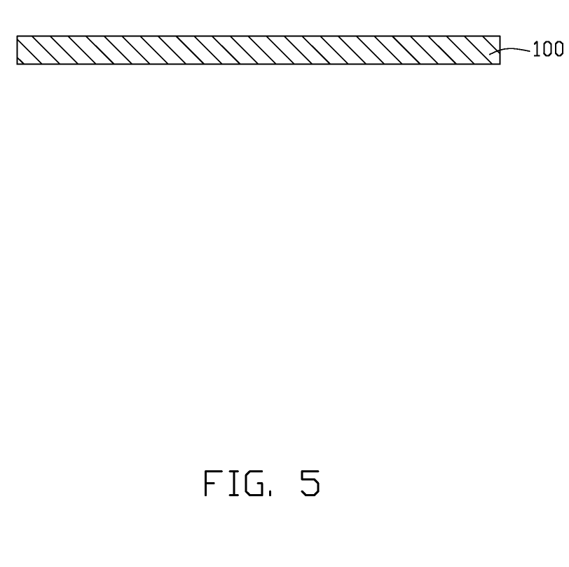

FIG. 4 is a flowchart of a method for manufacturing the circuit substrate 10 of the first embodiment, described here in accompaniment with FIGS. 5 to 11 in detail.

In step 1, referring to FIG. 5, a sacrificial layer 100 is provided. The sacrificial layer 100 can be made of a metal such as copper, aluminum, or nickel. A thickness of the sacrificial layer 100 can be from about 2 μms to about 200 μms.

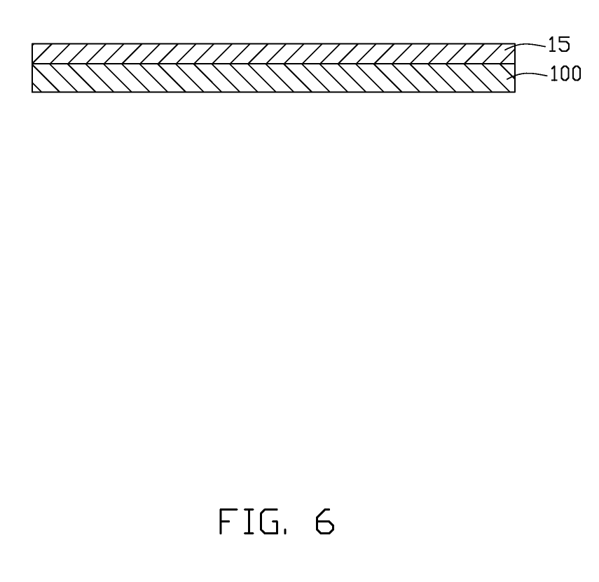

In step 2, referring to FIG. 6, a catalyst layer 15 is formed on the sacrificial layer 100. The catalyst layer 15 is configured for growing a CNT array, and can be iron, cobalt, nickel or alloys thereof.

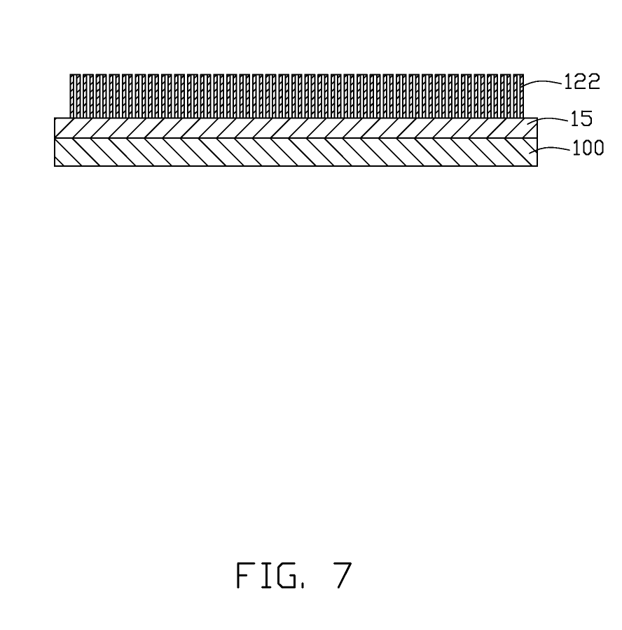

In step 3, referring to FIG. 7, a CNT array 122 including a plurality of CNTs 1220 is grown on the catalyst layer 15. In detail, the sacrificial layer 100 with the catalyst layer 15 formed thereon is placed on a carrier boat disposed in a reaction furnace, for example, a quartz tube, whereby temperature of the reaction furnace is elevated to about 700° C. to 1000° C. and a carbon source gas such as acetylene and ethylene is introduced into the reaction furnace, such that the CNT array 122 can grow from the catalyst layer 15. The height of the CNT array 122 can be controlled by time of reaction, and an extending direction of the CNT array 122 can be controlled with an electric field.

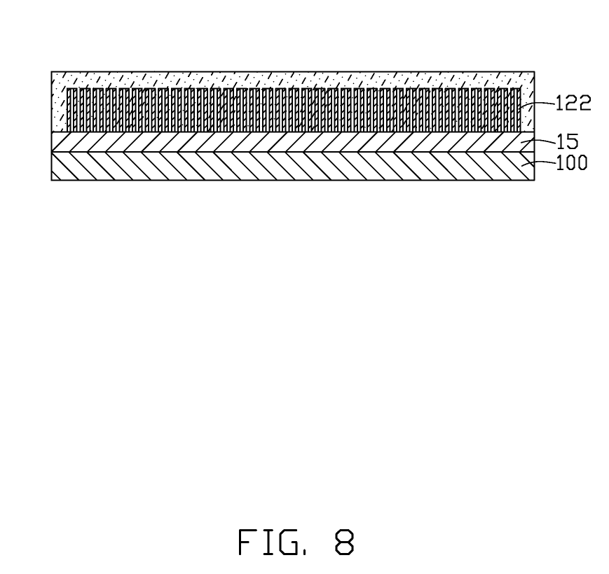

In step 4, referring to FIG. 8 to FIG. 10, the composite layer 12 is formed using the CNT array 122.

Referring to FIG. 8, an end of the CNT array 122 is covered by a polymer. In detail, a polymer precursor or a solution of the polymer precursor is applied on the CNT array 122 using dip-coating or brush coating, the CNT array 122 is embedded in the polymer precursor, and then the flexible polymer precursor is cured after that. Thus, crosslink reaction will occur in the polymer precursor, such that the end of the CNT array 122 is embedded in the cured polymer. Preferably, ultrasonic oscillation is performed during the process of coating the CNT array 122 so that the flexible polymer precursor can fully fill gaps in the CNT array 122.

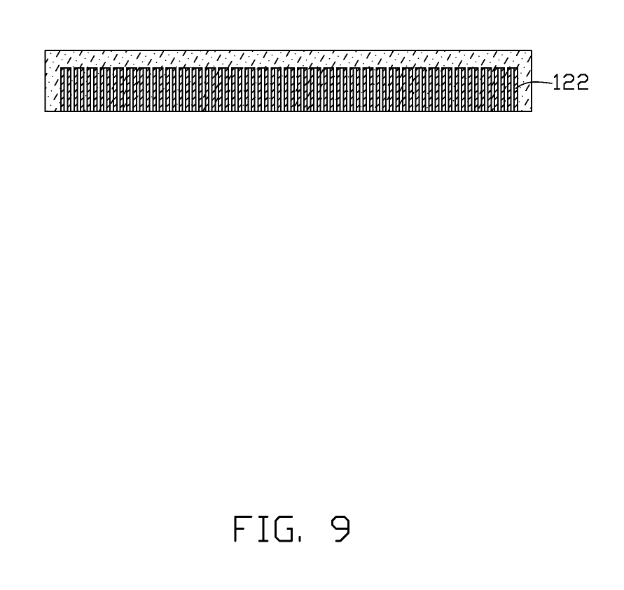

Referring to FIG. 8 and FIG. 9, the sacrificial layer 100 and the catalyst layer 15 are removed, by, for example, etching. When the sacrificial layer 100 is copper and the catalyst layer 15 is ferric oxide, a ferric chloride solution can be used to etch the sacrificial layer 100 and the catalyst layer 15.

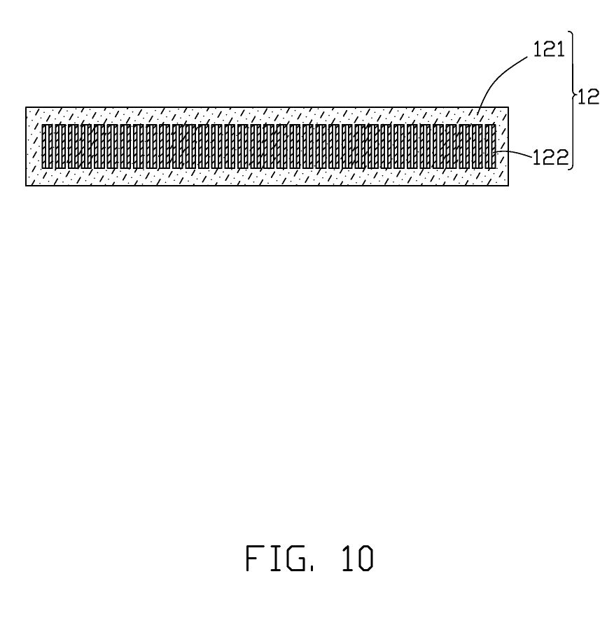

Thirdly, referring to FIG. 10, another end of the CNT array 122 is covered by the same polymer as step 4 using similar processes. Polymer matrix 121 is thus formed and the composite layer 12 is obtained.

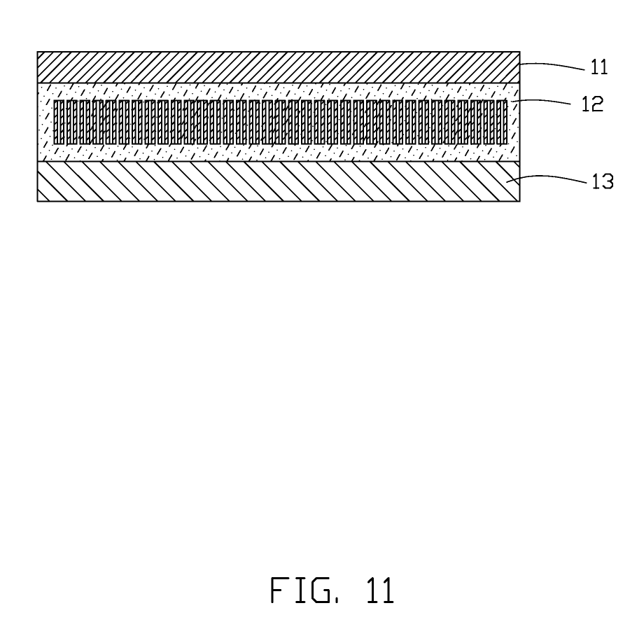

In step 5, referring to FIG. 11, the electrically conductive layer 11 and the metal base layer 13 are formed on two opposite surfaces of the composite layer 12.

In step 6, referring to FIG. 1, the electrically conductive layer 11 is processed to form electrically conductive traces 111 therein. The electrically conductive traces 111 can be formed by a photolithography process and an etching process. Thus, the circuit substrate 10 of the first embodiment is obtained.

It is understood that circuit substrates 20 and 30 can be fabricated by steps similar to those described.

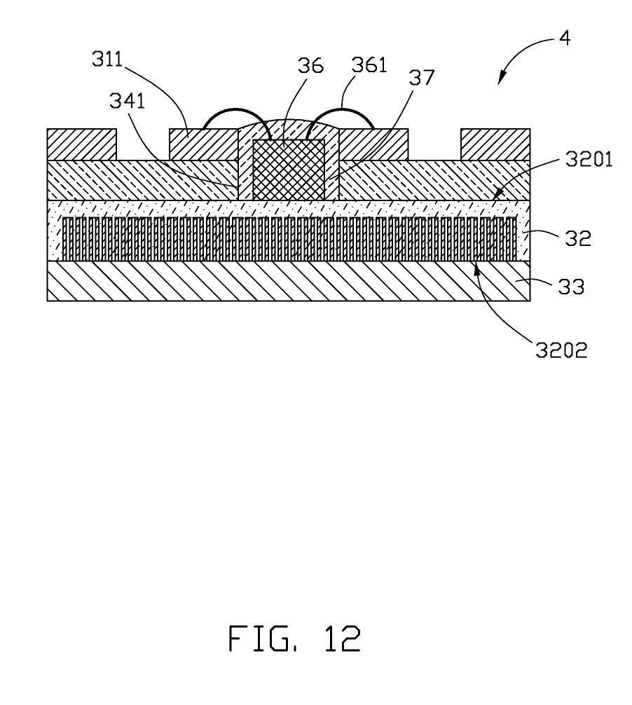

FIG. 12 is a cross sectional view of a circuit substrate assembly 4 comprising a circuit substrate 30 as shown in FIG. 3, and an electronic component 36 mounted thereon. The electronic component 36 can be a passive component, an active component, an optoelectronics element, a semiconductor chip or other suitable elements. The electronic component 36 is received in the through hole 341, encapsulated by epoxy resin 37, and electrically connected with the electrically conductive traces 311 via bonding wires 361.

Due to the high heat conductivity of CNTs of the composite layer 32, heat generated by the electronic component 36 can be efficiently conducted from the second surface 3202 of the composite layer 32 to the first surface 3201 thereof, and then dissipated by the metal base layer 33. Therefore, the circuit substrate assembly 4 has improved thermal dissipation.

It is understood that the electronic component 36 can also be mounted on the electrically conductive layers of the circuit substrates 10 and 20 via surface mounting technology, flip-chip mounting technology, or other mounting technologies.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

1. A circuit substrate for mounting an electronic component, comprising:
a metal base layer;
an electrically conductive layer having electrically conductive traces configured for electrically connecting to an electronic component; and
a composite layer sandwiched between the metal base layer and the electrically conductive layer, the composite layer comprising a polymer matrix and a plurality of carbon nanotubes embedded in the polymer matrix, the composite layer having a first surface in contact with the metal substrate and a second surface at an opposite side thereof to the first surface, each of the carbon nanotubes extending from the first surface to the second surface inclined at an angle of from 80° to 100° relative to the first surface.

2. The circuit substrate as claimed in claim 1, wherein the carbon nanotubes are parallel to each other.

3. The circuit substrate as claimed in claim 1, wherein a length of each of the carbon nanotubes is about 60%-90% of the thickness of the composite layer.

4. The circuit substrate as claimed in claim 1, wherein each of the carbon nanotubes comprises a first end and an opposite second end, the first end of each of the carbon nanotubes is adjacent to and spaced a distance from the first surface, and the second end of each of the carbon nanotubes is adjacent to and spaced a distance from the second surface.

5. The circuit substrate as claimed in claim 1, wherein each of the carbon nanotubes comprises a first end and an opposite second end, the first end of each of the carbon nanotubes is exposed at the first surface, the second end of each of the carbon nanotubes is adjacent to and spaced a distance from the second surface.

6. The circuit substrate as claimed in claim 1, wherein each of the carbon nanotubes comprises a first end and an opposite second end, the first end of each of the carbon nanotubes is adjacent to and spaced a distance from the first surface, the second end of each of the carbon nanotubes is exposed at the second surface.

7. The circuit substrate as claimed in claim 1, wherein a distance between each two neighboring carbon nanotubes is a constant.

8. The circuit substrate as claimed in claim 1, wherein the carbon nanotubes are distributed in the composite layer varying in a given direction perpendicular to a thickness direction of the composite layer.

9. The circuit substrate as claimed in claim 1, wherein a percentage by volume of the carbon nanotubes in the composite layer is from 40% to 80%.

10. The circuit substrate as claimed in claim 1, wherein the circuit substrate further comprises an insulating layer disposed between the electrically conductive layer and the metal base layer, and the second surface of the composite layer is in contact with the insulating layer.

11. The circuit substrate as claimed in claim 10, wherein the insulating layer defines a through hole therein, and the through hole is configured for accommodating the electronic component.

12. A circuit substrate assembly, comprising:
a metal base layer;
an electrically conductive layer having electrically conductive traces;
a composite layer disposed between the metal base layer and the electrically conductive layer, the composite layer comprising a polymer matrix and a plurality of carbon nanotubes embedded in the polymer matrix, the composite layer having a first surface in contact with the metal substrate and a second surface at an opposite side thereof to the first surface, each of the carbon nanotubes extending from the first surface to the second surface inclined at an angle from 80° to 100° relative to the first surface; and
an electronic component electrically connected with the electrically conductive traces.

13. The circuit substrate assembly as claimed in claim 12, wherein the electronic component is mounted on the electrically conductive layer.

14. The circuit substrate assembly as claimed in claim 12, wherein the circuit substrate assembly further comprises an insulating layer disposed between the electrically conductive layer and the metal base layer, the insulating layer defines a through hole therein, and the electronic component is received in the through hole.

15. The circuit substrate assembly as claimed in claim 14, wherein the electronic component is encapsulated by epoxy resin, and electrically connected with the electrically conductive traces via bonding wires.
